(19) United States
(12) Patent Application Publication
(10) Pub. No.: US 2025/0299746 A1
(43) Pub. Date: Sep. 25, 2025

(54) SEMICONDUCTOR STORAGE DEVICE

(71) Applicant: Kioxia Corporation, Tokyo (JP)

(72) Inventor: Kensuke YAMAMOTO, Yokohama Kanagawa (JP)

(21) Appl. No.: 19/059,190

(22) Filed: Feb. 20, 2025

(30) Foreign Application Priority Data
Mar. 21, 2024 (JP) 2024-045159

(51) Int. Cl. G11C 16/26; G11C 5/06; G11C 16/04

(52) U.S. Cl. CPC G11C 16/26; G11C 5/063; G11C 16/0483

(57) ABSTRACT

According to one embodiment, a semiconductor storage device includes a memory cell, a bit line electrically connected to the memory cell, a sense amplifier circuit electrically connected to the bit line, a first data wiring electrically connected to the sense amplifier circuit, a data latch circuit electrically connected to the first data wiring, and a second data wiring and a third data wiring electrically connected to the data latch circuit, for transferring mutually inverted data signals. The data latch circuit includes a first node that stores data and a second node that stores inverted data of the data. The second data wiring is electrically connected to the first node. The first data wiring and the third data wiring are electrically connected to the second node.

### CROSS-REFERENCE TO RELATED APPLICATION(S)

This application is based upon and claims the benefit of priority from Japanese Patent Application No. 2024-045159, filed Mar. 21, 2024, the entire contents of which are incorporated herein by reference.

### FIELD

Embodiments described herein relate generally to a semiconductor storage device.

### BACKGROUND

A semiconductor storage device that includes memory cells, bit lines electrically connected to the memory cells, and sense amplifier circuits electrically connected to the bit lines is known.

### BRIEF DESCRIPTION OF THE DRAWINGS

FIG. 1 is a schematic block diagram illustrating a configuration of a memory system according to a first embodiment.

FIG. 2 is a schematic block diagram illustrating a configuration of a portion of a memory die.

FIG. 3 is a schematic circuit diagram illustrating a configuration of a portion of the memory die.

FIG. 4 is a schematic perspective view illustrating a configuration of a portion of the memory die.

FIG. 5 is a schematic block diagram illustrating a configuration of a sense amplifier module.

FIG. 6 is a schematic block diagram illustrating a configuration of a cache memory.

FIG. 7 is a schematic circuit diagram illustrating a configuration of a latch circuit.

FIGS. 8-9 are timing charts illustrating an operation of the latch circuit during data-in.

FIGS. 10-11 are timing charts illustrating the operation of the latch circuit during data-out.

FIG. 12 is a schematic circuit diagram illustrating a configuration of a latch circuit according to a comparative example.

FIGS. 13-14 are timing charts illustrating an operation of the latch circuit according to the comparative example.

FIG. 15 is a schematic circuit diagram illustrating a configuration of a latch circuit according to a second embodiment.

FIG. 16 is a schematic circuit diagram illustrating a connection relationship between multiplexers according to a third embodiment.

FIG. 17 is a schematic circuit diagram illustrating a configuration of the multiplexer.

FIG. 18 is a timing chart illustrating an operation of the multiplexer during data-out.

FIG. 19 is a schematic circuit diagram illustrating a configuration of a multiplexer according to a fourth embodiment.

### DETAILED DESCRIPTION

Embodiments provide a semiconductor storage device with improved interface performance.

In general, according to one embodiment, a semiconductor storage device includes a memory cell, a bit line electrically connected to the memory cell, a sense amplifier circuit electrically connected to the bit line, a first data wiring electrically connected to the sense amplifier circuit, a data latch circuit electrically connected to the first data wiring, and a second data wiring and a third data wiring electrically connected to the data latch circuit, for transferring mutually inverted data signals. The data latch circuit includes a first node that stores data and a second node that stores inverted data of the data. The second data wiring is electrically connected to the first node. The first data wiring and the third data wiring are electrically connected to the second node.

Next, a semiconductor storage device according to an embodiment will be described in detail with reference to the drawings. The following embodiment is merely an example, and is not intended to limit the present disclosure.

In addition, when a “semiconductor storage device” is mentioned in this specification, it may mean a memory die or a memory system including a controller die, such as a memory chip, a memory card, or an SSD. It may also mean a configuration including a host computer, such as a smartphone, a tablet terminal, or a personal computer.

Further, in this specification, when it is mentioned that a first configuration is “electrically connected” to a second configuration, it may mean that the first configuration is directly connected to the second configuration, or may mean that the first configuration is connected to the second configuration via wirings, a semiconductor member, a transistor, or the like. For example, when three transistors are connected in series, a first transistor is “electrically connected” to a third transistor even when a second transistor is in an OFF state.

Further, in this specification, when it is mentioned that a first configuration is “connected between” a second configuration and a third configuration, it may mean that the first configuration, the second configuration, and the third configuration are connected in series, and that the first configuration is provided in a current path between the second configuration and the third configuration.

Further, in this specification, when it is mentioned that a circuit or the like “allows electrical conduction” between two wirings or the like, it may mean, for example, that the circuit or the like includes a transistor or the like, that the transistor or the like is provided in a current path between the two wirings, and that the transistor or the like is in an ON state.

### First embodiment

### Memory System 10

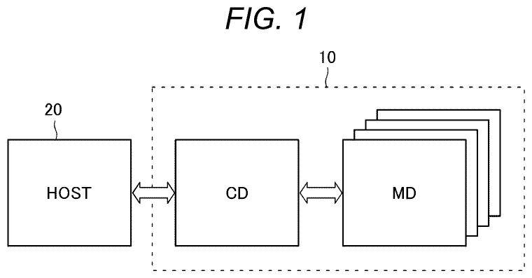

FIG. 1 is a schematic block diagram illustrating a configuration of a memory system 10 according to a first embodiment.

The memory system 10 performs a read operation, a write operation, an erase operation, and the like for user data in response to a signal transmitted from a host computer 20. The memory system 10 is, for example, a memory chip, a memory card, an SSD, or other systems capable of storing user data. The memory system 10 includes a plurality of memory dies MD and a controller die CD. The memory die MD stores user data. The controller die CD is connected to the plurality of memory dies MD and the host computer 20. The controller die CD includes, for example, a processor, a RAM, and the like. The controller die CD performs processing such as conversion between a logical address and a physical address, bit error detection/correction, garbage collection (also referred to as “compaction”), and wear leveling. The functions of the respective units of the controller die CD can be implemented by either dedicated hardware, a processor that executes a program, or a combination thereof.

### Configuration of Memory Die MD

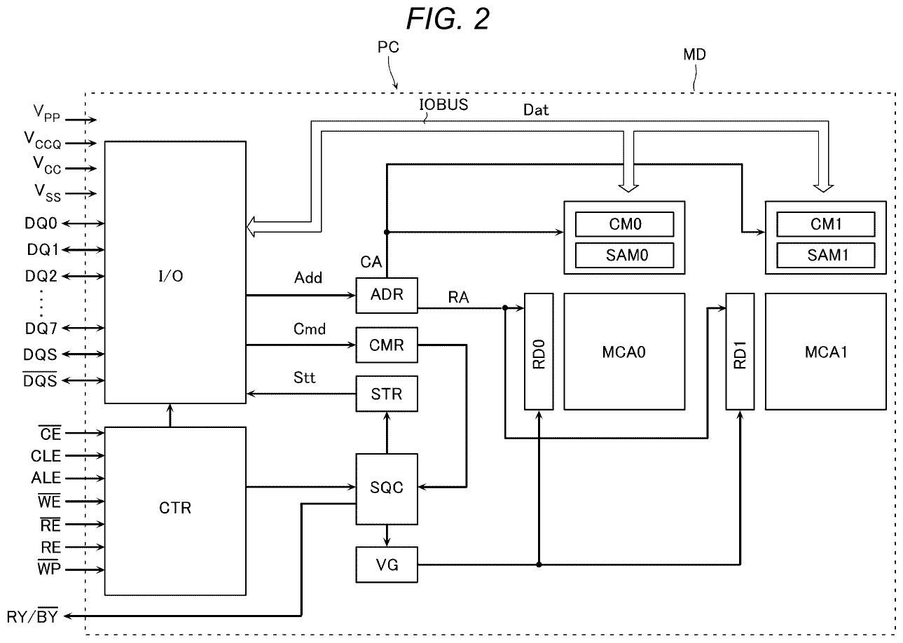

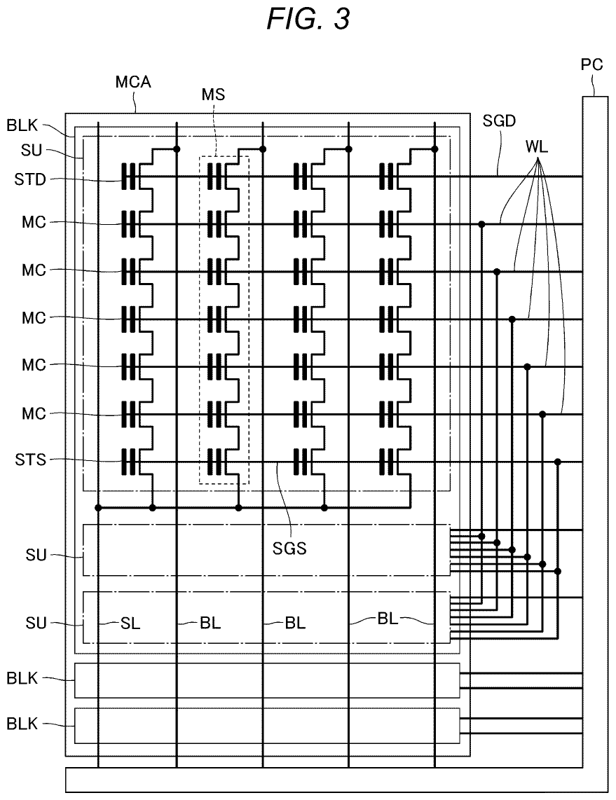

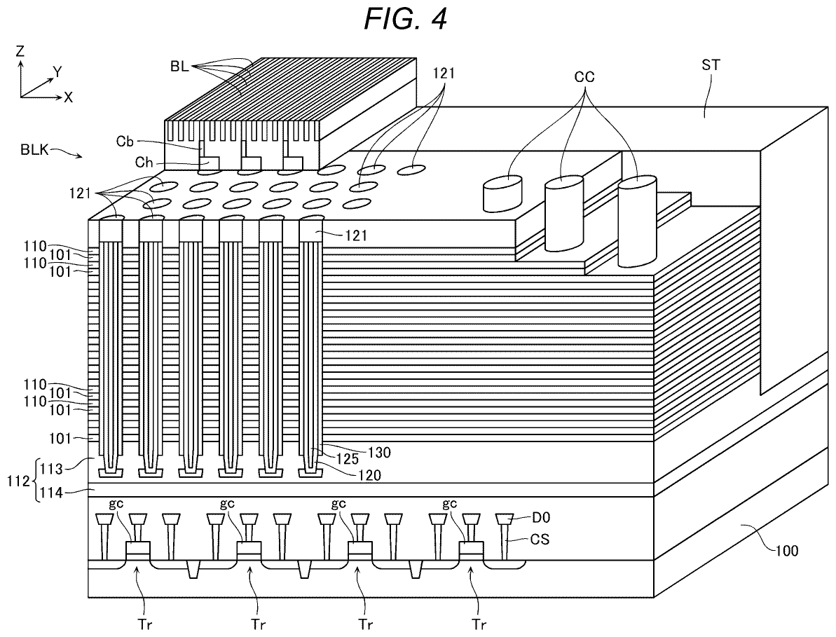

FIG. 2 is a schematic block diagram illustrating a configuration of the memory die MD according to the first embodiment. FIG. 3 is a schematic circuit diagram illustrating a configuration of a part of the memory die MD. FIG. 4 is a schematic perspective view illustrating a configuration of a part of the memory die MD.

FIG. 2 shows a plurality of control terminals, and the like. These plurality of control terminals may be represented as control terminals corresponding to high active signals (positive logic signals). Further, the plurality of control terminals may be represented as control terminals corresponding to low active signals (negative logic signals). Further, the plurality of control terminals may be represented as control terminals corresponding to both high active signals and low active signals. In FIG. 2, the reference numeral of the control terminal corresponding to the low active signal includes an overline. In this specification, the reference numeral of the control terminal corresponding to the low active signal includes a slash (“/”). The depiction in FIG. 2 is an example, and a specific aspect can be adjusted as appropriate. For example, it is possible to set some or all of the high active signals to be low active signals, and set some or all of the low active signals to be high active signals.

As illustrated in FIG. 2, the memory die MD includes memory cell arrays MCA0 and MCA1 that store user data, and a peripheral circuit PC connected to the memory cell arrays MCA0 and MCA1. In the following description, the memory cell arrays MCA0 and MCA1 may be referred to as a memory cell array MCA.

### Configuration of Memory Cell Array MCA

As illustrated in FIG. 3, the memory cell array MCA includes a plurality of memory blocks BLK. Each of the plurality of memory blocks BLK includes a plurality of string units SU. Each of the plurality of string units SU includes a plurality of memory strings MS. One end of cach of the plurality of memory strings MS is connected to the peripheral circuit PC via a bit line BL. In addition, the other end of each of the plurality of memory strings MS is connected to the peripheral circuit PC via a common source line SL.

The memory string MS includes a drain-side select transistor STD, a plurality of memory cells MC (memory transistors), and a source-side select transistor STS. The drain-side select transistor STD, the plurality of memory cells MC, and the source-side select transistor STS are connected in series between the bit line BL and the source line SL. Hereinafter, the drain-side select transistor STD and the source-side select transistor STS may be simply referred to as select transistors (STD, STS).

The memory cell MC is a field effect transistor. The memory cell MC includes a semiconductor layer, a gate insulating film, and a gate electrode. The semiconductor layer functions as a channel region. The gate insulating film includes a charge storage film. A threshold voltage of the memory cell MC changes depending on the amount of charge in the charge storage film. The memory cell MC stores one bit or a plurality of bits of data. A word line WL is connected to the gate electrodes of the plurality of memory cells MC corresponding to one string unit SU. Each of these word lines WL is connected in common to all the string units SU in one memory block BLK.

The select transistors (STD, STS) are field effect transistors. Each of the select transistors (STD, STS) includes a semiconductor layer, a gate insulating film, and a gate electrode. The semiconductor layer functions as a channel region. Select gate lines (SGD, SGS) are respectively connected to the gate electrodes of the select transistors (STD, STS). One drain-side select gate line SGD is connected in common to all the memory strings MS in one string unit SU. One source-side select gate line SGS is connected in common to all memory strings MS in one memory block BLK.

The memory cell array MCA is provided above a semiconductor substrate 100, for example, as illustrated in FIG. 4. In the example of FIG. 4, a plurality of transistors Tr constituting the peripheral circuit PC are provided between the semiconductor substrate 100 and the memory cell array MCA. The transistors Tr include a plurality of electrodes gc. The plurality of electrodes gc are connected to a wiring layer D0, and the like via contacts CS.

The memory cell array MCA includes a plurality of memory blocks BLK arranged in a Y direction. In addition, an inter-block insulating layer ST made of silicon oxide (SiO₂) or the like is provided between two memory blocks BLK adjacent to each other in the Y direction.

For example, as illustrated in FIG. 4, the memory block BLK includes a plurality of conductive layers 110 arranged in a Z direction, a plurality of semiconductor pillars 120 extending in the Z direction, and a plurality of gate insulating films 130 respectively provided between the plurality of conductive layers 110 and the plurality of semiconductor pillars 120.

The conductive layer 110 is a conductive layer having a substantially plate shape and extending in an X direction. The conductive layer 110 may include a stacked film of a barrier conductive film of such as titanium nitride (TiN) and a metal film of such as tungsten (W). The conductive layer 110 may also include polycrystalline silicon containing impurities such as phosphorus (P) or boron (B). An insulating layer 101 of such as silicon oxide (SiO₂) is provided between the plurality of conductive layers 110 arranged in the Z direction.

Among the plurality of conductive layers 110, one or more conductive layers 110 located in the lowermost layer or layers function as the gate electrodes of the source-side select gate line SGS (FIG. 3) and the plurality of source-side select transistors STS connected thereto. These plurality of conductive layers 110 are electrically independent for each memory block BLK.

In addition, the plurality of conductive layers 110 located above this function as the gate electrodes of the word line WL (FIG. 3) and the plurality of memory cells MC connected thereto (FIG. 3). These plurality of conductive layers 110 are electrically independent for each memory block BLK.

In addition, one or more conductive layers 110 located above this function as the gate electrodes of the drain-side select gate line SGD and the plurality of drain-side select transistors STD connected thereto (FIG. 3). These plurality of conductive layers 110 are electrically independent for each string unit SU.

A conductive layer 112 is provided below the conductive layers 110. The conductive layer 112 may include polycrystalline silicon containing impurities such as phosphorus (P) or boron (B). The insulating layer 101 of such as silicon oxide (SiO₂) is provided between the conductive layer 112 and the lowermost conductive layer 110. The conductive layer 112 may include a semiconductor layer 113 and a conductive layer 114 connected to the lower surface of the semiconductor layer 113. The semiconductor layer 113 may include polycrystalline silicon containing impurities such as phosphorus (P) or boron (B). The conductive layer 114 may include a metal such as tungsten (W), a conductive layer such as tungsten silicide, or other conductive layers.

The conductive layer 112 functions as a source line SL (FIG. 3). The source line SL is provided in common to all memory blocks BLK in the memory cell array MCA, for example.

The semiconductor pillars 120 are arranged in a predetermined pattern in the X and Y directions, for example, as illustrated in FIG. 4. Each of the semiconductor pillars 120 function as channel regions for the plurality of memory cells MC and the select transistors (STD, STS) in one memory string MS (FIG. 3). The semiconductor pillar 120 is, for example, a semiconductor layer of such as polycrystalline silicon (Si). The semiconductor pillar 120 has a substantially cylindrical shape, for example, as illustrated in FIG. 4, and an insulating layer 125 of such as silicon oxide is provided in the center portion thereof. The outer peripheral surface of the semiconductor pillar 120 is surrounded by the conductive layer 110 and faces the conductive layer 110.

An impurity region 121 containing an N-type impurity such as phosphorus (P) is provided at an upper end of the semiconductor pillar 120. The impurity region 121 is connected to the bit line BL via a contact Ch and a contact Cb.

The gate insulating film 130 has a substantially cylindrical shape that covers the outer peripheral surface of the semiconductor pillar 120. The gate insulating film 130 includes, for example, a tunnel insulating film, a charge storage film, and a block insulating film stacked between the semiconductor pillar 120 and the conductive layer 110. The tunnel insulating film and the block insulating film are, for example, insulating films such as silicon oxide (SiO₂). The charge storage film is, for example, silicon nitride (Si₃N₄), and is a film capable of storing charges. The tunnel insulating film, the charge storage film, and the block insulating film have a substantially cylindrical shape and extend in the Z direction along the outer peripheral surface of the semiconductor pillar 120 except for a contact portion between the semiconductor pillar 120 and the conductive layer 112.

The gate insulating film 130 may include a floating gate of such as polycrystalline silicon containing N-type or P-type impurities in place of the charge storage film.

A plurality of contacts CC are provided at the ends of the plurality of conductive layers 110 in the X direction. The plurality of conductive layers 110 are connected to the peripheral circuit PC (FIG. 2) through the plurality of contacts CC. As illustrated in FIG. 4, the plurality of contacts CC extend in the Z direction and are connected to the conductive layer 110 at their lower ends. The contacts CC may include, for example, a stacked film of a barrier conductive film of such as titanium nitride (TiN) and a metal film of such as tungsten (W).

### Configuration of Peripheral Circuit PC

For example, as illustrated in FIG. 2, the peripheral circuit PC includes row decoders RD0 and RD1, sense amplifier modules SAM0 and SAM1, and cache memories CM0 and CM1 (also referred to as “data registers”) which are respectively connected to the memory cell arrays MCA0 and MCA1. The peripheral circuit PC also includes a voltage generation circuit VG and a sequencer SQC. The peripheral circuit PC also includes an input/output control circuit I/O, a logic circuit CTR, an address register ADR, a command register CMR, and a status register STR. In the following description, the row decoders RD0 and RD1 may be referred to as row decoders RD, the sense amplifier modules SAM0 and SAM1 may be referred to as sense amplifier modules SAM, and the cache memories CM0 and CM1 may be referred to as cache memories CM.

### Configuration of Row Decoder RD

The row decoder RD includes an address decoder that decodes address data Add, and a block selection circuit and a voltage selection circuit that transfer an operating voltage to the memory cell array MCA in response to an output signal of the address decoder.

The address decoder sequentially refers to the row address RA of the address register ADR in response to, for example, a control signal from the sequencer SQC and decodes the row address RA to set a predetermined block select transistor and a voltage select transistor corresponding to the row address RA to be in an ON state and set the other block select transistors and voltage select transistors to be in an OFF state.

### Configuration of Sense Amplifier Module SAM

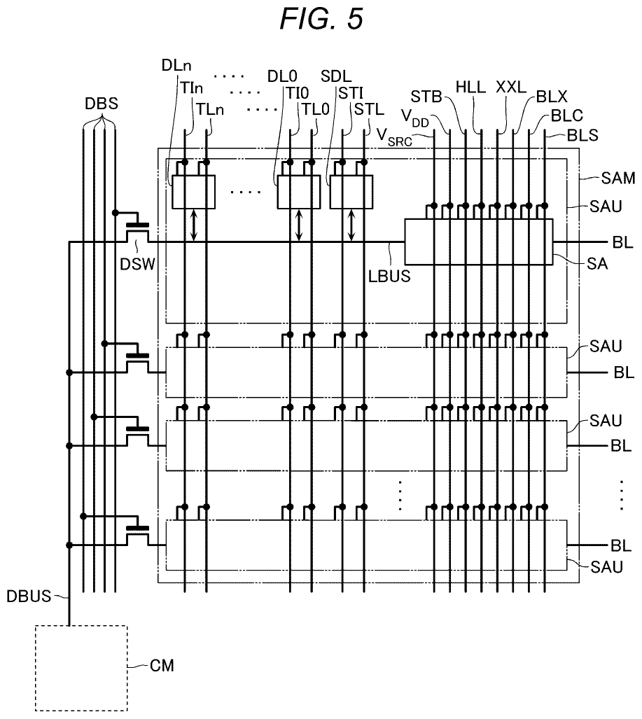

FIG. 5 is a schematic block diagram illustrating a configuration of the sense amplifier module SAM. The sense amplifier module SAM includes a plurality of sense amplifier units SAU, for example, as illustrated in FIG. 5. The plurality of sense amplifier units SAU correspond to the plurality of bit lines BL, respectively. Each sense amplifier unit SAU includes a sense amplifier SA, a wiring LBUS, and latch circuits SDL and DL0 to DLn (n is a natural number). The plurality of wirings LBUS are connected to one wiring DBUS via a switch transistor DSW.

The sense amplifier SA includes, for example, a sense circuit corresponding to cach of the plurality of bit lines BL. The sense circuit detects the voltage or current of the bit line BL and outputs data indicating a detection result. The latch circuits SDL and DL0 to DLn (n is a natural number) store the data output from the sense circuit, user data Dat input from the cache memory CM, and the like.

The switch transistor DSW is, for example, an NMOS transistor. The switch transistor DSW is connected between the wiring LBUS and the wiring DBUS. The gate electrode of the switch transistor DSW is connected to the sequencer SQC via a signal line DBS (FIG. 5).

As illustrated in FIG. 5, the above-described signal lines STB, HLL, XXL, BLX, BLC, and BLS are connected in common to all of the sense amplifier units SAU in the sense amplifier module SAM. In addition, a voltage supply line to which the voltage V_{DD} is supplied and a voltage supply line to which the voltage V_{SRC} is supplied are connected in common to all of the sense amplifier units SAU in the sense amplifier module SAM. Further, the signal lines STI and STL of the latch circuit SDL are connected in common to all of the sense amplifier units SAU in the sense amplifier module SAM. Similarly, signal lines TI0 to Tin and TL0 to TLn corresponding to the signal lines STI and STL in the latch circuits DL0 to DLn are connected in common to all of the sense amplifier units SAU in the sense amplifier module SAM. On the other hand, the above-described plurality of signal lines DBS are provided to connect in a one-to-one manner to the sense amplifier units SAU in the sense amplifier module SAM.

### Configuration of Cache Memory CM

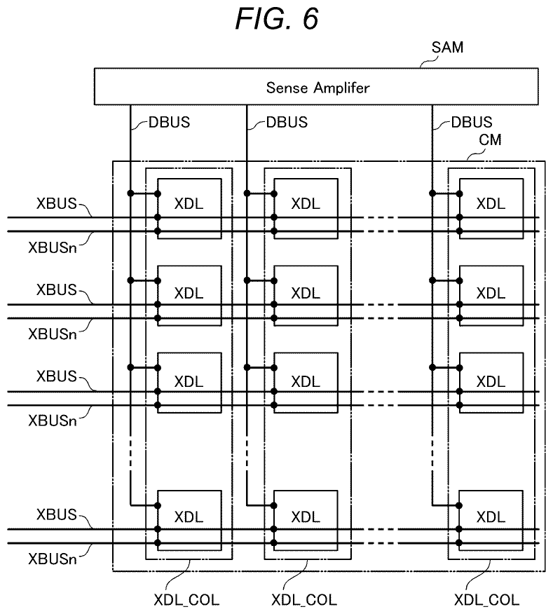

FIG. 6 is a schematic block diagram illustrating a configuration of the cache memory CM. The cache memory CM includes a plurality of latch circuit rows XDL_COL, for example, as illustrated in FIG. 6.

The latch circuit row XDL_COL includes a plurality of latch circuits XDL. The plurality of latch circuits XDL in one latch circuit row XDL_COL are connected to one wiring DBUS.

Each of the latch circuits XDL is connected to a pair of wirings XBUS and XBUSn. Although not illustrated in FIG. 6, a multiplexer is connected between the wirings XBUS and XBUSn and a bus wiring IOBUS (FIG. 2).

The plurality of latch circuits XDL in the cache memory CM are provided, for example, corresponding to the bit lines BL. The same number of plurality of latch circuits XDL as the number of bit lines BL may be provided.

The user data Dat included in the latch circuit XDL is transferred sequentially to the sense amplifier module SAM (FIG. 5) via the wiring DBUS during a write operation to be described later. In addition, the user data Dat included in the latch circuit in the sense amplifier module SAM is transferred sequentially to the latch circuit XDL (FIG. 6) during a read operation to be described later.

In addition, the user data Dat contained in the latch circuit XDL is transferred sequentially to the input/output control circuit I/O (FIG. 2) via the wirings XBUS and XBUSn during a data-out operation to be described later. The user data Dat is transferred from the input/output control circuit I/O to the latch circuit XDL (FIG. 6) via the wirings XBUS and XBUSn during a data-in operation to be described later.

A specific configuration of the latch circuit XDL will be described later.

A column decoder (not illustrated) is connected to the cache memory CM. The column decoder decodes the column address CA stored in the address register ADR (FIG. 2) and selects the latch circuit XDL corresponding to the column address CA.

### Configuration of Voltage Generation Circuit VG

The voltage generation circuit VG (FIG. 2) includes, for example, a step-down circuit such as a regulator and a step-up circuit such as a charge pump circuit. The step-down circuits and the step-up circuits are connected to power supply terminals V_{CC} and V_{PP} to which a power supply voltage is supplied, and a ground terminal V_{SS} to which a ground voltage is supplied, via voltage supply lines. Each of the power supply terminals V_{CC} and V_{PP}, and the ground terminal V_{SS} is implemented, for example, by a pad electrode.

The voltage generation circuit VG generates a plurality of operating voltages to be applied to the bit lines BL, the source lines SL, the word lines WL, and the select gate lines (SGD, SGS) during a read operation, a write operation, and an crase operations performed on the memory cell array MCA in response to control signals from the sequencer SQC, and outputs them simultaneously to the plurality of voltage supply lines. The operating voltages output from the voltage supply lines are appropriately adjusted in response to control signals from the sequencer SQC.

### Configuration of Sequencer SQC

The sequencer SQC outputs internal control signals to the row decoders RD0 and RD1, the sense amplifier modules SAM0 and SAM1, and the voltage generation circuit VG in accordance with command data Cmd stored in the command register CMR. The sequencer SQC also appropriately outputs status data Stt, which indicates the state of the internal operation of the memory die MD, to the status register STR.

### Configuration of Address Register ADR

As illustrated in FIG. 2, the address register ADR is connected to the input/output control circuit I/O and stores address data Add input from the input/output control circuit I/O. The address register ADR includes, for example, a plurality of 8-bit register strings. When an internal operation such as a read operation, a write operation, or an crase operation is executed, the register string stores a plurality of pieces of address data Add including address data Add corresponding to an operation being executed and address data Add corresponding to the next operation to be executed.

The address data Add includes, for example, a column address CA and a row address RA. The row address RA includes, for example, a block address that specifies the memory block BLK (FIG. 3), a page address that specifies the string unit SU and the word line WL, a plane address that specifies the memory cell array MCA (planc), and a chip address that specifies the memory die MD.

### Configuration of Command Register CMR

The command register CMR is connected to the input/output control circuit I/O and stores the command data Cmd input from the input/output control circuit I/O. The command register CMR includes, for example, at least one set of 8-bit register strings. When the command data Cmd is stored in the command register CMR, a control signal is input to the sequencer SQC.

### Configuration of Status Register STR

The status register STR is connected to the input/output control circuit I/O and stores the status data Stt to be output to the input/output control circuit I/O. The status register STR includes, for example, a plurality of 8-bit register strings.

### Configuration of Input/Output Control Circuit I/O

The input/output control circuit I/O (FIG. 2) includes data signal input/output terminals DQ0 to DQ7, data strobe signal input/output terminals DQS and/DQS, a shift register, and a buffer circuit. Each circuit in the input/output control circuit I/O is connected to a power supply terminal Veco to which a power supply voltage is supplied, and a ground terminal Vss. The power supply terminal Veco is implemented, for example, by a pad electrode.

Each of the data signal input/output terminals DQ0 to DQ7 and the data strobe signal input/output terminals DQS and/DQS is implemented, for example, by a pad electrode. Data input via the data signal input/output terminals DQ0 to DQ7 is input from the buffer circuit to the cache memory CM, the address register ADR, and the command register CMR in response to an internal control signal from the logic circuit CTR. The data output via the data signal input/output terminals DQ0 to DQ7 is input to the buffer circuit from the cache memory CM and the status register STR in response to an internal control signal from the logic circuit CTR. The functions of the data strobe signal input/output terminals DQS and/DQS will be described later.

### Configuration of Logic Circuit CTR

The logic circuit CTR (FIG. 2) includes a plurality of external control terminals /CE, CLE, ALE, /WE, /RE, RE, and /WP, and a logic circuit connected to the plurality of external control terminals /CE, CLE, ALE, /WE, /RE, RE, and /WP. The logic circuit CTR receives inputs of external control signals from the controller die CD via the external control terminals /CE, CLE, ALE, /WE, /RE, RE, and /WP, and outputs internal control signals to the input/output control circuit I/O in response to the external control signals.

### Operation of Memory Die MD

Next, the operation of the memory die MD will be described.

The memory die MD is configured to be able to execute a read operation. The read operation is an operation in which the sense amplifier module SAM (FIG. 2) reads the user data Dat from the memory cell array MCA, stores the read user data Dat in a latch circuit in the sense amplifier module SAM, and transfers the user data Dat to the latch circuit XDL (FIG. 6) in the cache memory CM. In the read operation, the user data Dat read from the memory cell array MCA is transferred to the latch circuit XDL via the bit line BL, the sense amplifier module SAM, and the wiring DBUS.

The memory die MD is also configured to be able to execute data-out. The data-out is an operation of outputting the user data Dat included in the latch circuit XDL (FIG. 6) in the cache memory CM to the controller die CD (FIG. 1). In the data-out, the user data Dat included in the latch circuit XDL is output to the controller die CD via the wirings XBUS and XBUSn, the bus wiring IOBUS, and the input/output control circuit I/O.

The memory die MD is also configured to be able to execute a write operation. The write operation is an operation of storing the user data Dat input from the controller die CD in the latch circuit in the sense amplifier module SAM and writing the user data Dat to the memory cell MC in the memory cell array MCA. In the write operation, a program operation of storing electrons in the charge storage film of the memory cell MC and a verification operation of determining whether the threshold voltage of the memory cell MC has increased to a target value are executed once or a plurality of times.

The memory die MD is also configured to be able to execute data-in. The data-in is an operation of inputting the user data Dat input from the controller die CD to the latch circuit XDL (FIG. 6). In the data-in, the user data Dat is input to the latch circuit XDL via the input/output control circuit I/O, the bus wiring IOBUS, and the wirings XBUS and XBUSn.

The memory die MD is also configured to be able to execute an erase operation. The crase operation is an operation of erasing data written in the memory cells MC in the memory cell array MCA. In the crase operation, an erase voltage supply operation of drawing out electrons from the charge storage film of the memory cell MC and a verification operation of determining whether the threshold voltage of the memory cell MC has decreased to a target value are performed once or a plurality of times.

### Latch Circuit XDL10

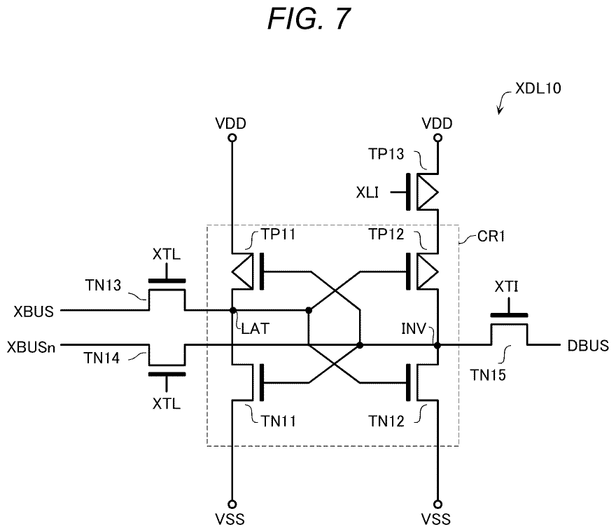

Next, a latch circuit XDL10 will be described as a configuration example of the latch circuit XDL. FIG. 7 is a schematic circuit diagram illustrating a configuration of the latch circuit XDL10.

The wirings XBUS and XBUSn are input/output wirings on the input/output control circuit I/O side of the latch circuit XDL10 and the wiring DBUS are an input/output wiring on the sense amplifier module SAM side of the latch circuit XDL10. The wirings XBUS and XBUSn are signal lines that transmit complementary signals. For example, mutually inverted signals are transmitted through the wirings XBUS and XBUSn.

The latch circuit XDL10 (FIG. 7) includes transistors TN11 to TN15, transistors TP11 to TP13, a node LAT, and a node INV. The transistors TN11 to TN15 are N-channel MOS transistors. The transistors TP11 to TP13 are P-channel MOS transistors.

The transistors TP11 and TN11 are connected in series to a current path between a power supply voltage node VDD and a ground voltage node VSS via the node LAT. Gate electrodes of the transistors TP11 and TN11 are connected to a node INV. The transistors TP11 and TN11 function as an inverter circuit.

A power supply voltage, for example, a voltage V_{D} is supplied to the power supply voltage node VDD. A voltage smaller than the voltage V_{D}, for example, a voltage V_{S} is supplied to the ground voltage node VSS.

The transistors TP12 and TN12 are connected in series to a current path between the power supply voltage node VDD and the ground voltage node VSS via the node INV. Gate electrodes of the transistors TP12 and TN12 are connected to the node LAT. The transistors TP12 and TN12 function as an inverter circuit.

Hereinafter, a part including the transistors TP11, TN11, TP12, and TN12 will be referred to as a circuit CR1. In the circuit CR1, two inverter circuits are cross-connected.

The transistor TN13 is connected between the wiring XBUS and the node LAT. The transistor TN14 is connected between the wiring XBUSn and the node INV. The gate electrodes of the transistors TN13 and TN14 are connected to a signal supply line XTL. The transistors TN13 and TN14 function as a switch circuit that is turned on or off in response to a signal of the signal supply line XTL.

The transistor TP13 is connected to a current path between the power supply voltage node VDD and the transistor TP12. The gate electrode of the transistor TP13 is connected to a signal supply line XLI. The transistor TP13 functions as a switch circuit that is turned on or off in response to a signal of the signal supply line XLI.

The transistor TN15 is connected between the node INV and the wiring DBUS. The gate electrode of the transistor TN15 is connected to a signal supply line XTI. The transistor TN15 functions as a switch circuit that is turned on or off in response to a signal of the signal supply line XTI.

### Operation of Latch Circuit XDL10 during Data-In

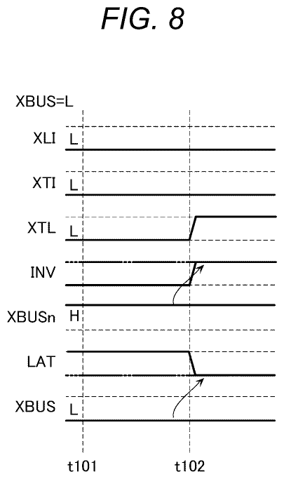

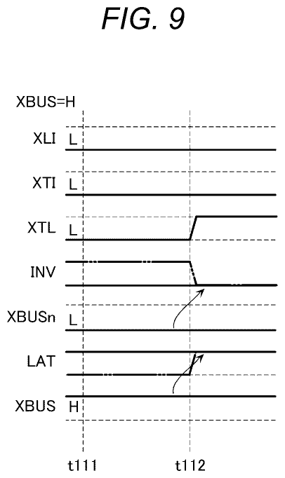

FIGS. 8 and 9 are timing charts illustrating the operation of the latch circuit XDL10 during data-in. During data-in, signals that are input via the wirings XBUS and XBUSn are transferred to the nodes LAT and INV of the latch circuit XDL10 and are stored in the nodes LAT and INV. Mutually inverted signals are stored in the nodes LAT and INV.

In the following description, a high-level signal “H” has a magnitude for turning off a P-channel MOS transistor and turning on an N-channel MOS transistor. The “H” is a magnitude that is approximately the same as a power supply voltage, for example, the voltage V_{D}. A low-level signal “L” has a magnitude for turning on a P-channel MOS transistor and turning off an N-channel MOS transistor. “L” is a magnitude that is approximately the same as the voltage V_{S}, for example.

FIG. 8 is a timing chart when “L” is input from the wiring XBUS and “H” is input from the wiring XBUSn.

During data-in, the signal supply line XTI is maintained at “L”, and the transistor TN15 is turned off, thereby disconnecting the node INV from the wiring DBUS. In addition, the signal supply line XLI is maintained at “L”, and the transistor TP13 is turned on.

At timing t101, the nodes INV and LAT are either in an “H” state and an “L” state or in an “L” state and an “H” state. In addition, “L” is supplied from the signal supply line XTL, and the transistors TN13 and TN14 are in an OFF state.

At timing t102, a data-in operation is executed. In the data-in operation, the signal supply line XTL is raised from “L” to “H”, and the transistors TN13 and TN14 are turned on. Thereby, a signal voltage “L” from the wiring XBUS is transferred to the node LAT, and a signal voltage “H” from the wiring XBUSn is transferred to the node INV, whereby the node LAT is set to “L” and the node INV is set to “H”.

As described above, the user data Dat is transferred from the input/output control circuit I/O to the latch circuit XDL10.

FIG. 9 is a timing chart when “H” is input from the wiring XBUS and “L” is input from the wiring XBUSn.

The state of each wiring at timing t111 is basically the same as the state of each wiring at timing t101, except for the wirings XBUS and XBUSn.

At timing t112, the same data-in operation as that performed at timing t102 is executed. Thereby, the signal voltage “H” from the wiring XBUS is transferred to the node LAT, and the signal voltage “L” from the wiring XBUSn is transferred to the node INV, whereby the node LAT is set to “H” and the node INV is set to “L”.

As described above, the user data Dat is transferred from the input/output control circuit I/O to the latch circuit XDL10.

### Operation of Latch Circuit XDL10 during Data-Out

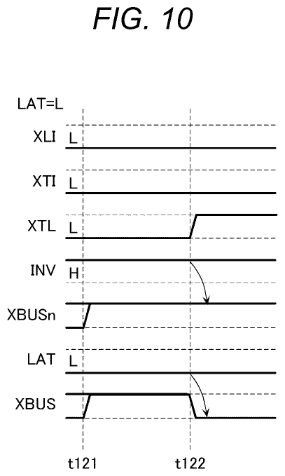

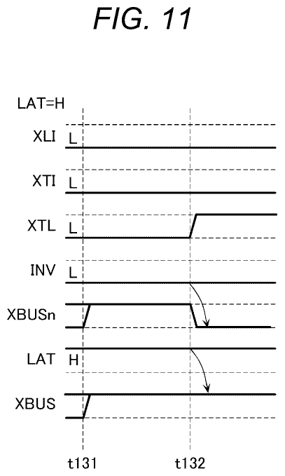

FIGS. 10 and 11 are timing charts illustrating the operation of the latch circuit XDL10 during data-out. During data-out, signals that are stored in the nodes LAT and INV of the latch circuit XDL10 are output to the input/output control circuit I/O via the wirings XBUS and XBUSn.

FIG. 10 is a timing chart when data-out is performed from when the node LAT is in an “L” state and the node INV is in an “H” state.

During data-out, the signal supply line XTI is maintained at “L”, and the transistor TN15 is turned off, thereby disconnecting the node INV from the wiring DBUS. Further, the signal supply line XLI is maintained at “L”, and the transistor TP13 is turned on.

At timing t121, the signal supply line XTL is in an “L” state, and the transistors TN13 and TN14 are in an OFF state. Since the node LAT is in an “L” state and the node INV is in an “H” state, the transistors TP12 and TN11 are in an ON state, and the transistors TP11 and TN12 are in an OFF state. Further, at timing t121, precharge is performed, and the wirings XBUS and XBUSn are set to be in an “H” state.

At timing t122, a data-out operation is performed. In the data-out operation, the signal supply line XTL is raised from “L” to “H” and the transistors TN13 and TN14 are turned on. Thereby, the wiring XBUS is discharged via the two transistors TN13 and TN11 that are turned on, and changes from “H” to “L”. The wiring XBUSn is maintained at “H” because no discharge occurs after the precharge.

As described above, the user data Dat is transferred from the latch circuit XDL10 via the wirings XBUS and XBUSn.

FIG. 11 is a timing chart when data-out is performed from when the node LAT is in an “H” state and the node INV is in an “L” state.

The state of each wiring at timing t131 is basically the same as the state of each wiring at timing t121, except for the nodes LAT and INV. However, since the node LAT is in an “H” state and the node INV is in an “L” state, the transistors TP11 and TN12 are in an ON state and the transistors TP12 and TN11 are in an OFF state.

At timing t132, the same data-out operation as that performed at timing t122 is executed. Thereby, the wiring XBUSn is discharged via the two transistors TN14 and TN12 that are turned on, and changes from “H” to “L”. The wiring XBUS is maintained at “H” because no discharge occurs after the precharge.

As described above, the user data Dat is transferred from the latch circuit XDL10 to the input/output control circuit I/O.

### COMPARATIVE EXAMPLE

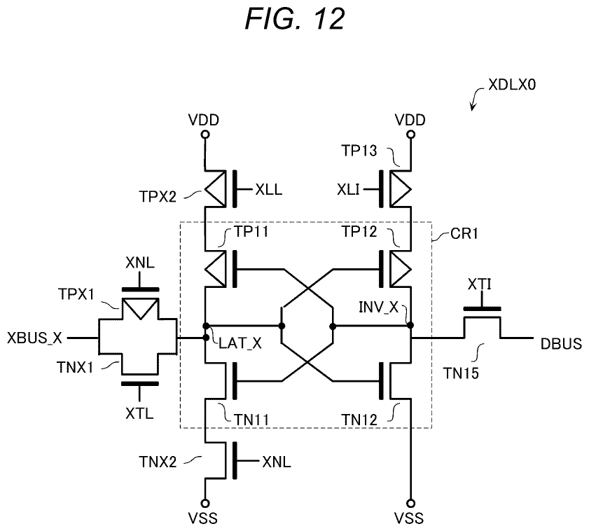

Next, a latch circuit according to a comparative example will be described with reference to FIGS. 12 to 14. FIG. 12 is a schematic circuit diagram illustrating a configuration of the latch circuit according to the comparative example.

Instead of the wirings XBUS and XBUSn (FIG. 7), only a wiring XBUS_X (FIG. 12) is connected to a latch circuit XDLX0 according to the comparative example as an input/output wiring on the input/output control circuit I/O side. Further, in the latch circuit XDLX0, the transistors TN13 and TN14 (FIG. 7) are not provided, but transistors TPX1 and TNX1 are provided between the wiring XBUS_X and the node LAT_X. The wiring XBUS_X is connected to the node LAT_X via the transistors TPX1 and TNX1, and is not connected to the node INV_X.

Further, in the latch circuit XDLX0, a transistor TPX2 is provided between the power supply voltage node VDD and the transistor TP11, and a transistor TNX2 is provided between the transistor TN11 and the ground voltage node VSS. The transistors TNX1 and TNX2 are N-channel MOS transistors. The transistors TPX1 and TPX2 are P-channel MOS transistors.

Further, signal supply lines XNL and XLL are connected to the latch circuit XDLX0 (FIG. 12). The gate electrodes of the transistors TNX2 and TPX1 are connected to the signal supply line XNL. The gate electrode of the transistor TNX1 is connected to the signal supply line XTL. The gate electrode of the transistor TPX2 is connected to the signal supply line XLL.

### Operation of Latch Circuit XDLX0 during Data-In

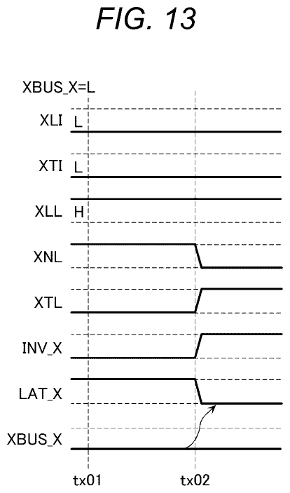

FIG. 13 is a timing chart illustrating the operation of the latch circuit according to the comparative example during data-in. During data-in, a signal that is input via the wiring XBUS_X is transferred to and stored in the node LAT_X of the latch circuit XDLX0, and an inverted signal of the node LAT_X is stored in the node INV_X.

FIG. 13 is a timing chart when “L” is input from the wiring XBUS_X.

During data-in, the signal supply line XTI is maintained at “L” and the transistor TN15 is turned off, thereby disconnecting the node INV_X from the wiring DBUS. In addition, the signal supply line XLI is maintained at “L”, and the transistor TP13 is turned on. The signal supply line XLL is maintained at “H”, and the transistor TPX2 is turned off.

At timing tx01, the nodes INV_X and LAT_X are in an “L” state and an “H” state, and thus the transistors TP11 and TN12 are in an ON state, and the transistors TP12 and TN11 are in an OFF state. In addition, the signal supply lines XNL and XTL are in an “H” state and an “L” state, the transistor TNX2 is in an ON state, and the transistors TPX1 and TNX1 are in an OFF state.

At timing tx02, the signal supply lines XNL and XTL are set to “L” and “H”, so that the transistors TPX1 and TNX1 are turned on, and the transistor TNX2 is turned off. Thereby, the signal voltage “L” from the wiring XBUS_X is transferred to the node LAT_X, and the node LAT_X is set to “L”. Here, “L” of LAT_X is input to the input of the inverter circuit configured with the transistors TP12 and TN12, and the transistors TP12 and TP13 are turned on, and thus the node INV_X has the same potential as that of the power supply voltage node VDD and is set to “H”.

### Operation of Latch Circuit XDLX0 during Data-Out

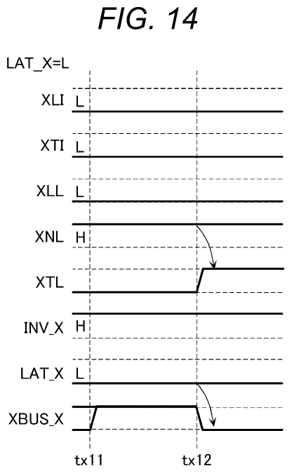

FIG. 14 is a timing chart illustrating the operation of the latch circuit according to the comparative example during data-out. During data-out, a signal stored in the node LAT_X of the latch circuit XDLXO is output to the input/output control circuit I/O via the wiring XBUS_X.

FIG. 14 is a timing chart when data-out is performed from when the node LAT_X is in an “L” state and the node INV_X is in an “H” state.

During data-out, the signal supply line XTI is maintained at “L”, the transistor TN15 is turned off, thereby disconnecting the node INV_X from the wiring DBUS. Further, the signal supply lines XLI and XLL are maintained at “L”, and the transistors TP13 and TPX2 are turned on. Further, the signal supply line XNL is maintained at “H”, the transistor TPX1 is turned off, and the transistor TNX2 is turned on.

At timing tx11, the signal supply line XTL is in an “L” state, and the transistor TNX1 is in an OFF state. Since the node LAT_X is in an “L” state and the node INV_X is in an “H” state, the transistors TP12 and TN11 are in an ON state and the transistors TP11 and TN12 are in an OFF state. In addition, at timing tx 11, precharge is performed and the wiring XBUS_X is set to be in an “H” state.

At timing tx 12, the signal supply line XTL is raised from “L” to “H”, and the transistor TNX1 is turned on. Thereby, the wiring XBUS_X is discharged via the three transistors TNX1, TN11, and TNX2 that are turned on, and changes from “H” to “L”.

In the latch circuit XDLX0 according to the comparative example, a discharge path when the voltage level of the precharged wiring XBUS_X falls from “H” to “L” at timing tx12 includes three transistors (transistors TNX1, TN11, and TNX2). In this manner, the discharge path of the wiring XBUS_X includes a relatively large number of transistors and has high resistance, which may result in a long discharge time. Thus, it may be difficult to speed up a latch operation.

### Effects

In the latch circuit XDL10 (FIG. 7) according to the first embodiment, when the transistors TN13 and TN14 are turned on during data-in, voltages related to the data are transferred directly from the wirings XBUS and XBUSn to the nodes LAT and INV. Thereby, in this embodiment, the transistors TPX2 and TNX2 that function as switches required during data-in in the comparative example are not necessary.

Further, in the latch circuit XDL10, the wirings XBUS and XBUSn are both set to “H” during data-out by precharge. At timing t122 (FIG. 10), a discharge path when the voltage level of the precharged wiring XBUS changes from “H” to “L” includes two transistors (transistors TN13 and TN11). In this manner, the discharge path includes a relatively small number of transistors and has a low resistance, and thus a discharge time of the wiring XBUS can be made relatively short. Thus, it is possible to speed up the latch operation.

Further, in order to speed up the discharge of the wiring XBUS described above, it is also conceivable to increase the size (for example, a channel width) of the transistor in a current path to reduce resistance. However, since a large number of latch circuits XDL10 are disposed corresponding to the bit lines BL, an increase in a transistor area of each latch circuit XDL10 leads to a significant increase in an area occupied by transistors in a chip, which is not preferable.

In this embodiment, the operation of the latch circuit XDL10 related to data-out can be speeded up without increasing the number or size of the transistors in the latch circuit XDL10. Thereby, it is possible to improve interface performance of the semiconductor storage device.

### Second Embodiment

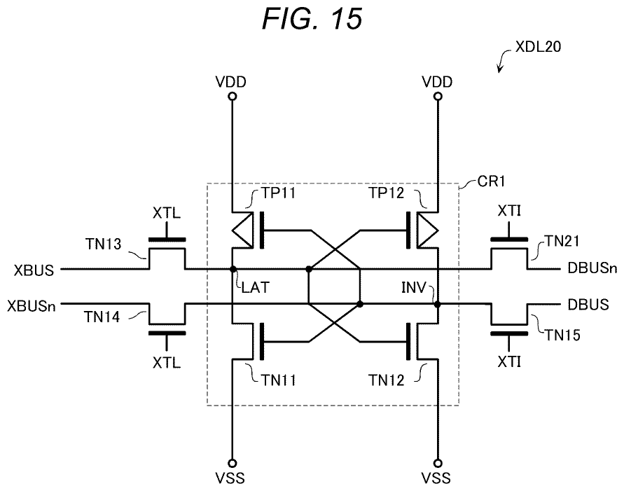

FIG. 15 is a circuit diagram illustrating a configuration of a latch circuit XDL20 according to a second embodiment. In FIG. 15, the same components as those in FIG. 7 are denoted by the same reference numerals, and the description thereof will be omitted.

A semiconductor storage device according to the second embodiment is basically configured in the same manner as the semiconductor storage device according to the first embodiment. However, in the latch circuit XDL10 according to the first embodiment (FIG. 7), the wiring DBUS is connected between the sense amplifier module SAM and the latch circuit XDL10, whereas in the latch circuit XDL20 according to the second embodiment (FIG. 15), a wiring DBUSn is connected between a sense amplifier module SAM and the latch circuit XDL20 in addition to a wiring DBUS. Further, unlike the latch circuit XDL10, the latch circuit XDL20 is not provided with a transistor TP13.

The wirings DBUS and DBUSn are signal lines for transmitting complementary signals. The wirings DBUS and DBUSn transmit mutually inverted signals.

In the latch circuit XDL20, the wiring DBUSn is connected to a node LAT, and a transistor TN21 is provided between the wiring DBUSn and the node LAT. The transistor TN21 is an N-channel MOS transistor.

In a read operation of the semiconductor storage device according to the second embodiment, data is transferred from the sense amplifier module SAM to the latch circuit XDL20 via the wiring DBUS and DBUSn. In such a case, data can be input directly from the wiring DBUS and DBUSn to the nodes LAT and INV, and thus the transistor TP13 in the latch circuit XDL10 (FIG. 7) is not necessary. In such a configuration in which the transistor TP13 (FIG. 7) is not provided, a charge time when changing the potential stored in the node INV from “L” to “H” is reduced, thereby making it possible to speed up the operation of the latch circuit XDL20.

### Third Embodiment

In the first and second embodiments, the configurations of the latch circuit XDL10 (FIG. 7) and the latch circuit XDL20 (FIG. 15) are described. In a third embodiment, a configuration of a multiplexer that can be used in combination with latch circuits XDL10 and XDL20 will be described.

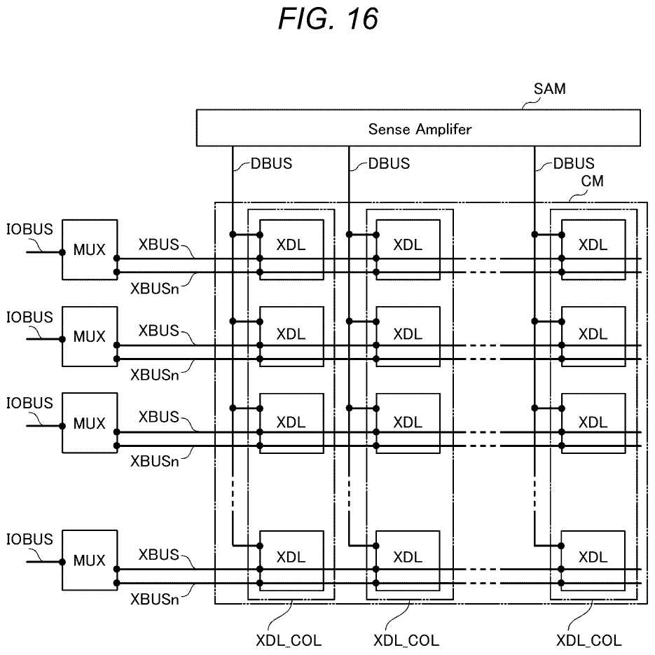

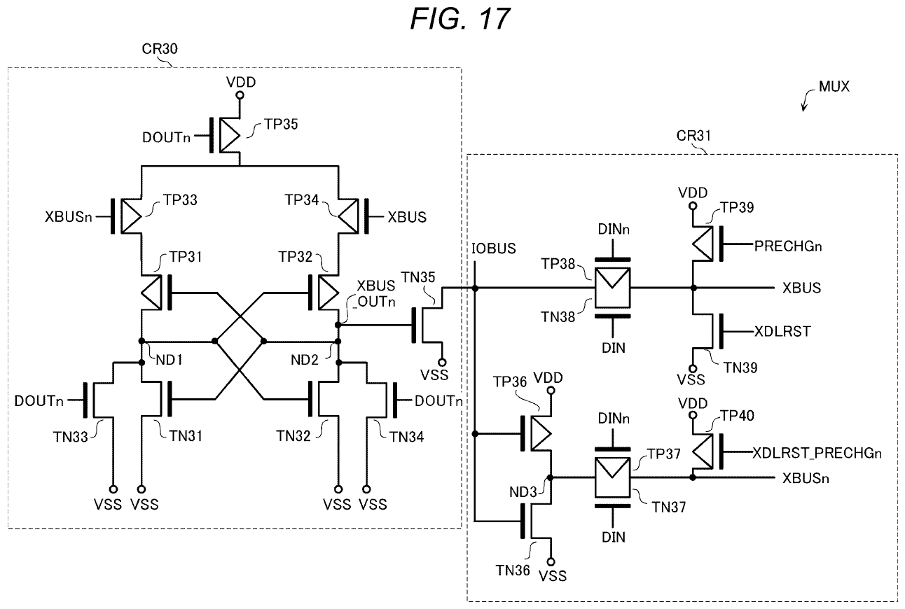

FIG. 16 is a circuit diagram illustrating a connection relationship between multiplexers MUX according to the third embodiment. FIG. 17 is a schematic circuit diagram illustrating a configuration of the multiplexer MUX. In FIG. 16, the same components as those in FIG. 6 are denoted by the same reference numerals, and the description thereof will be omitted.

The semiconductor storage device according to the third embodiment is basically configured in the same manner as the semiconductor storage device according to the first embodiment. However, in the semiconductor storage device according to the third embodiment, the multiplexer MUX according to the third embodiment (FIG. 16) is connected between wirings XBUS and XBUSn and a bus wiring IOBUS.

The multiplexer MUX (FIG. 17) includes circuits CR30 and CR31 connected between the bus wiring IOBUS and the wirings XBUS and XBUSn.

The circuit CR30 includes transistors TN31 to TN35, transistors TP31 to TP35, a node ND1, a node ND2, and a node XBUS_OUTn. During data-out, the circuit CR30 of the multiplexer MUX is operated.

The circuit CR31 includes transistors TN36 to TN39, transistors TP36 to TP40, and a node ND3. During data-in, the circuit CR31 of the multiplexer MUX is operated.

The transistors TN31 to TN39 are N-channel MOS transistors. The transistors TP31 to TP40 are P-channel MOS transistors.

The transistors TP31 and TN31 are connected in series to a current path between the power supply voltage node VDD and the ground voltage node VSS via the node ND1. The gate electrodes of the transistors TP31 and TN31 are connected to the node ND2. The transistors TP31 and TN31 function as an inverter circuit.

The transistors TP32 and TN32 are connected in series to a current path between the power supply voltage node VDD and the ground voltage node VSS via the node ND2. The gate electrodes of the transistors TP32 and TN32 are connected to the node ND1. The transistors TP32 and TN32 function as an inverter circuit.

In a part including the transistors TP31 and TN31 and the transistors TP32 and TN32, two inverter circuits are cross-connected.

The transistor TP33 is connected between the power supply voltage node VDD and the transistor TP31. The gate electrode of the transistor TP33 is connected to the wiring XBUSn. The transistor TP33 functions as a switch circuit that is turned on or off in response to a signal of the wiring XBUSn.

The transistor TP34 is connected between the power supply voltage node VDD and the transistor TP32. The gate electrode of the transistor TP34 is connected to the wiring XBUS. The transistor TP34 functions as a switch circuit that is turned on or off in response to a signal of the wiring XBUS.

The transistor TN33 is connected in parallel with the transistor TN31 between the node ND1 and the ground voltage node VSS. The transistor TN34 is connected in parallel with the transistor TN32 between the node ND2 and the ground voltage node VSS. The transistor TP35 is connected between the power supply voltage node VDD and the transistors TP33 and TP34. The gate electrodes of the transistors TN33, TN34, and TP35 are connected to a signal supply line DOUTn. The transistors TP33, TN34, and TN35 function as a switch circuit that is turned on or off in response to a signal of the signal supply line DOUTn.

The transistor TN35 is connected between the bus wiring IOBUS and the ground voltage node VSS. The gate electrode of the transistor TN35 is connected to the node ND2. The transistor TN35 functions as a switch circuit that reduces or maintains the voltage of the bus wiring IOBUS by discharge in accordance with the state of the node ND2.

The transistors TP36 and TN36 are connected in series to a current path between the power supply voltage node VDD and the ground voltage node VSS via the node ND3. The gate electrodes of the transistors TP36 and TN36 are connected to the bus wiring IOBUS. The transistors TP36 and TN36 function as an inverter circuit.

The transistors TP37 and TN37 are connected in parallel to a current path between the node ND3 and the wiring XBUSn. The transistors TP38 and TN38 are connected in parallel to a current path between the bus wiring IOBUS and the wiring XBUS. The gate electrodes of the transistors TP37 and TP38 are connected to a signal supply line DINn. The gate electrodes of the transistors TN37 and TN38 are connected to a signal supply line DIN. The transistors TP37, TN37, TP38, and TN38 function as a switch circuit that is turned on or off in response to signals of the signal supply lines DINn and DIN.

The transistors TP39 and TN39 are connected in series to a current path between the power supply voltage node VDD and the ground voltage node VSS. The node between the transistors TP39 and TN39 is connected to the wiring XBUS. The gate electrode of the transistor TP39 is connected to a signal supply line PRECHGn. The gate electrode of the transistor TN39 is connected to a signal supply line XDLRST. The transistor TP39 functions as a switch circuit for precharging the wiring XBUS to an “H” level. The transistor TN39 functions as a switch circuit for resetting the wiring XBUS to an “L” level.

The transistor TP40 is connected to a current path between the power supply voltage node VDD and the wiring XBUSn. The gate electrode of the transistor TP40 is connected to a signal supply line XDLRST_PRECHGn. The transistor TP40 functions as a switch circuit for precharging or resetting the wiring XBUSn.

### Operation of Multiplexer MUX during Data-Out

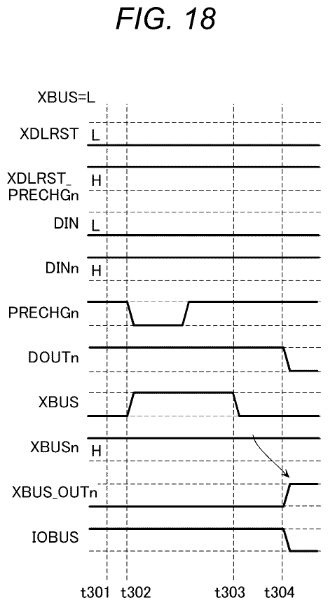

FIG. 18 is a timing chart illustrating the operation of the multiplexer MUX during data-out.

During data-out, the signals stored in the nodes LAT and INV of the latch circuit XDL10 (FIG. 7) and the latch circuit XDL20 (FIG. 12) are input to the circuit CR30 in the MUX via the wirings XBUS and XBUSn, and are output to the input/output control circuit I/O via the bus wiring IOBUS.

FIG. 18 is a timing chart when data-out is performed from when the wiring XBUS is in an “L” state and the wiring XBUSn is in an “H” state. Since the wiring XBUS is in an “L” state and the wiring XBUSn is in an “H” state, the transistor TP34 is turned on, and the transistor TP33 is turned off.

During data-out, the signal supply lines XDLRST and DIN are maintained at “L”, the signal supply lines XDLRST_PRECHGn and DINn are maintained at “H”, the transistors TN37 to TN39 and the transistors TP37, TP38, and TP40 in the circuit CM31 are turned off, and the circuit CM31 is not operated.

At timing t301, the signal supply line PRECHGn is set to “H”. Thereby, the transistor TP39 is turned off. In addition, “H” is supplied to the signal supply line DOUTn, the transistor TP35 is turned off, and the transistors TN33 and TN34 are turned on. Thereby, the nodes ND1, ND2, and XBUS_OUTn are set to “L” which is the same potential as the ground voltage node VSS. As a result, the bus wiring IOBUS is not discharged and is in an “H” state, and the transistors TP31 and TP32 are turned on.

At timing t302, the signal supply line PRECHGn is lowered from “H” to “L”, and is then raised to “H” after a certain period of time. Thereby, the transistor TP39 is turned on for a certain period of time, and the wiring XBUS is charged from “L” to “H”. When the wiring XBUS is set to “H”, the transistor TP34 is turned off.

At timing t303, data is transferred from the node LAT of the latch circuit XDL10 (FIG. 7), the latch circuit XDL20 (FIG. 12), or the like to the wiring XBUS, and the wiring XBUS is set to “L”. Thereby, the transistor TP34 is turned on.

At timing t304, the signal supply line DOUTn is lowered from “H” to “L”, the transistor TP35 is turned on, and the transistors TN33 and TN34 are turned off. Since the transistors TP35, TP34, and TP32 are turned on, the nodes ND2 and XBUS_OUTn are set to “H” which is the same potential as the power supply voltage node. In addition, the transistor TP31 is turned off, and the node NDI is discharged via the transistor TN31 and changes from “H” to “L”. Thereby, the transistor TN32 is turned off. In addition, the transistor TN35 is turned on, and the bus wiring IOBUS is set to “L”.

### Operation of Multiplexer MUX during Data-In

During data-in, the signal supply lines DIN and DINn are set to “H” and “L”, and the transistors TN37, TN38, TP37, and TP38 are turned on. Thereby, data transferred from the bus wiring IOBUS is transferred to the wiring XBUS. In addition, the data transferred from the bus wiring IOBUS is inverted via the inverter circuit configured with the transistors TN36 and TP36, and the inverted data is output from the wiring XBUSn.

### Fourth Embodiment

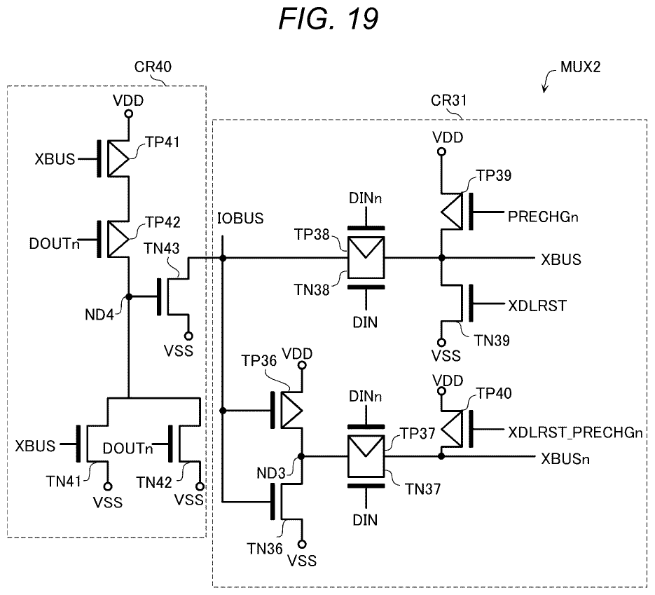

FIG. 19 is a schematic circuit diagram illustrating a configuration of a multiplexer MUX2 according to a fourth embodiment. In FIG. 19, the same components as those of the multiplexer MUX in FIG. 17 are denoted by the same reference numerals, and the description thereof will be omitted.

The multiplexer MUX2 according to the fourth embodiment (FIG. 19) is basically configured in the same manner as the multiplexer MUX according to the third embodiment (FIG. 17). However, the multiplexer MUX2 is provided with a circuit CR40 instead of the circuit CR30 of the multiplexer MUX.

The circuit CR40 includes transistors TN41 to TN43, transistors TP41 and TP42, and a node ND4. During data-out, the circuit CR40 of the multiplexer MUX2 is operated.

The transistors TN41 to TN43 are N-channel MOS transistors. The transistors TP41 and TP42 are P-channel MOS transistors.

The transistors TP41 and TP42 are connected in series to a current path between a power supply voltage node VDD and the node ND4. The transistors TN41 and TN42 are connected in parallel to a current path between the node ND4 and a ground voltage node VSS. The gate electrodes of the transistors TP41 and TN41 are connected to a wiring XBUS. The gate electrodes of the transistors TP42 and TN42 are connected to a signal supply line DOUTn. The transistors TN41 and TN42 and the transistors TP41 and TP42 function as a NOR circuit including two input terminals connected to the wiring XBUS and the signal supply line DOUTn, and an output terminal connected to the node ND4.

The transistor TN43 is connected between a bus wiring IOBUS and the ground voltage node VSS. The gate electrode of the transistor TN43 is connected to the node ND4. The transistor TN43 functions as a switch circuit that reduces or maintains the voltage of the bus wiring IOBUS by discharge in accordance with the state of the node ND4.

The operation of the multiplexer MUX2 during data-in is the same as that of the multiplexer MUX (FIG. 17).

The operation of the multiplexer MUX2 during data-out is, for example, to previously precharge the bus wiring IOBUS to set it to “H”.

When “L” is input to the wiring XBUS and the signal supply line DOUTn, the transistors TN41 and TN42 are turned off, and the transistors TP41 and TP42 are turned on. Thereby, the node ND4 is set to “H” which is the same potential as the power supply voltage node VDD, the transistor TN43 is turned on, and the bus wiring IOBUS is discharged and set to “L”.

When “H” is input to at least one of the wiring XBUS and the signal supply line DOUTn, at least one of the transistors TN41 and TN42 is turned on, and at least one of the transistors TP42 and TN42 is turned off. Thereby, the node ND4 is set to “L” which is the same potential as the ground voltage node VSS, the transistor TN43 is not turned on, and the bus wiring IOBUS is maintained at “H”.

### Others

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a memory cell;
a bit line electrically connected to the memory cell;
a sense amplifier circuit electrically connected to the bit line;
a first data wiring electrically connected to the sense amplifier circuit;
a data latch circuit electrically connected to the first data wiring; and
a second data wiring and a third data wiring electrically connected to the data latch circuit, for transferring mutually inverted data signals, wherein
the data latch circuit includes a first node that stores data and a second node that stores inverted data of the data,
the second data wiring is electrically connected to the first node, and
the first data wiring and the third data wiring are electrically connected to the second node.

2. The semiconductor storage device according to claim 1, wherein the data latch circuit further includes
a first voltage node,
a second voltage node for supplying a voltage lower than that of the first voltage node,
a first P-channel MOS transistor and a first N-channel MOS transistor connected in series to a first current path between the first voltage node and the second voltage node via the first node, and
a second P-channel MOS transistor and a second N-channel MOS transistor connected in series to a second current path different from the first current path between the first voltage node and the second voltage node via the second node,
gate electrodes of the first P-channel MOS transistor and the first N-channel MOS transistor are connected to the second node, and
gate electrodes of the second P-channel MOS transistor and the second N-channel MOS transistor are connected to the first node.

3. The semiconductor storage device according to claim 1, further comprising a fourth data wiring electrically connected to the sense amplifier circuit and the data latch circuit, for transferring an inverted data signal of a data signal transmitted through the first data wiring,
wherein the fourth data wiring is electrically connected to the first node.

4. The semiconductor storage device according to claim 1, further comprising:
a first MOS transistor connected between the second data wiring and the first node; and
a second MOS transistor connected between the third data wiring and the second node.

5. The semiconductor storage device according to claim 1, further comprising:
a multiplexer electrically connected to the second data wiring and the third data wiring; and
a fifth data wiring electrically connected to the multiplexer,
wherein the multiplexer includes
a first switch circuit electrically connected between the fifth data wiring and the second data wiring,
a first inverter circuit including an input terminal electrically connected to the fifth data wiring, and
a second switch circuit electrically connected between an output terminal of the first inverter circuit and the third data wiring.

6. The semiconductor storage device according to claim 5, wherein the multiplexer further includes
a third voltage node,
a fourth voltage node for supplying a voltage lower than that of the third voltage node,
a third MOS transistor and a second inverter circuit connected in series to a third current path between the third voltage node and the fourth voltage node,
a fourth MOS transistor and a third inverter circuit connected in series to a fourth current path different from the third current path between the third voltage node and the fourth voltage node, and
a fifth MOS transistor including a gate electrode electrically connected to an output terminal of the second inverter circuit and an input terminal of the third inverter circuit,
the second data wiring is connected to a gate electrode of the third MOS transistor,
the third data wiring is connected to a gate electrode of the fourth MOS transistor,
an input terminal of the second inverter circuit is electrically connected to an output terminal of the third inverter circuit, and
the fifth MOS transistor is electrically connected between the fifth data wiring and the fourth voltage node.

7. The semiconductor storage device according to claim 5, wherein the multiplexer further includes
a NOR circuit having a first input node connected to the second wiring and a second input node connected to a control signal;
a fifth voltage node, and
a sixth MOS transistor including a gate electrode electrically connected to an output node of the NOR circuit, and
the sixth MOS transistor is electrically connected between the fifth data wiring and the fifth voltage node.

8. The semiconductor storage device according to claim 7, wherein the NOR circuit includes:
a seventh MOS transistor and an eighth MOS transistor connected in series between a sixth voltage node and the output node of the NOR circuit, and
a ninth MOS transistor and a tenth MOS transistor connected in parallel between the output node of the NOR circuit and a seventh voltage node, wherein
gate electrodes of the seventh MOS transistor and the ninth MOS transistor are connected to the first input node of the NOR circuit, and
gate electrodes of the eighth MOS transistor and the tenth MOS transistor are connected to the second input node of the NOR circuit.

9. The semiconductor storage device according to claim 1, wherein the memory cell includes
a semiconductor layer extending in a first direction,
a conductive layer facing the semiconductor layer in a second direction intersecting the first direction,
a charge storage layer provided between the semiconductor layer and the conductive layer, and
an insulating layer provided between the semiconductor layer and the charge storage layer.

10. A semiconductor storage device comprising:
a memory cell array;
a data latch circuit configured to store data read from the memory cell array and data to be written in the memory cell array;
a first data wiring electrically connected to the data latch circuit and through which the data read from the memory cell array is received and the data to be written in the memory cell array is transmitted; and
a second data wiring and a third data wiring electrically connected to the data latch circuit, for transferring mutually inverted data signals, wherein
the data latch circuit includes a first node that stores data and a second node that stores inverted data of the data,
the second data wiring is electrically connected to the first node, and
the first data wiring and the third data wiring are electrically connected to the second node.

11. The semiconductor storage device according to claim 10, wherein the data latch circuit further includes
a first voltage node,
a second voltage node for supplying a voltage lower than that of the first voltage node,
a first P-channel MOS transistor and a first N-channel MOS transistor connected in series to a first current path between the first voltage node and the second voltage node via the first node, and
a second P-channel MOS transistor and a second N-channel MOS transistor connected in series to a second current path different from the first current path between the first voltage node and the second voltage node via the second node,
gate electrodes of the first P-channel MOS transistor and the first N-channel MOS transistor are connected to the second node, and
gate electrodes of the second P-channel MOS transistor and the second N-channel MOS transistor are connected to the first node.

12. The semiconductor storage device according to claim 10, further comprising a fourth data wiring electrically connected to the sense amplifier circuit and the data latch circuit, for transferring an inverted data signal of a data signal transmitted through the first data wiring,
wherein the fourth data wiring is electrically connected to the first node.

13. The semiconductor storage device according to claim 10, further comprising:
a first MOS transistor connected between the second data wiring and the first node; and
a second MOS transistor connected between the third data wiring and the second node.

14. The semiconductor storage device according to claim 10, further comprising:
an input/output circuit electrically connected to data signal pins through which data signals are to be received and transmitted;
a fifth data wiring; and
a multiplexer electrically connected to the input/output circuit through the fifth data wiring, and to the data latch circuit through the second data wiring and the third data wiring.

15. The semiconductor storage device according to claim 14, wherein the multiplexer includes
a first switch circuit electrically connected between the fifth data wiring and the second data wiring,
a first inverter circuit including an input terminal electrically connected to the fifth data wiring, and
a second switch circuit electrically connected between an output terminal of the first inverter circuit and the third data wiring.

16. The semiconductor storage device according to claim 15, wherein the multiplexer further includes
a third voltage node,
a fourth voltage node for supplying a voltage lower than that of the third voltage node,
a third MOS transistor and a second inverter circuit connected in series to a third current path between the third voltage node and the fourth voltage node,
a fourth MOS transistor and a third inverter circuit connected in series to a fourth current path different from the third current path between the third voltage node and the fourth voltage node, and
a fifth MOS transistor including a gate electrode electrically connected to an output terminal of the second inverter circuit and an input terminal of the third inverter circuit,
the second data wiring is connected to a gate electrode of the third MOS transistor,
the third data wiring is connected to a gate electrode of the fourth MOS transistor,
an input terminal of the second inverter circuit is electrically connected to an output terminal of the third inverter circuit, and
the fifth MOS transistor is electrically connected between the fifth data wiring and the fourth voltage node.

17. The semiconductor storage device according to claim 15, wherein the multiplexer further includes
a NOR circuit having a first input node connected to the second wiring and a second input node connected to a control signal;
a fifth voltage node, and
a sixth MOS transistor including a gate electrode electrically connected to an output node of the NOR circuit, and
the sixth MOS transistor is electrically connected between the fifth data wiring and the fifth voltage node.

18. The semiconductor storage device according to claim 17, wherein the NOR circuit includes:
a seventh MOS transistor and an eighth MOS transistor connected in series between a sixth voltage node and the output node of the NOR circuit, and
a ninth MOS transistor and a tenth MOS transistor connected in parallel between the output node of the NOR circuit and a seventh voltage node, wherein
gate electrodes of the seventh MOS transistor and the ninth MOS transistor are connected to the first input node of the NOR circuit, and
gate electrodes of the eighth MOS transistor and the tenth MOS transistor are connected to the second input node of the NOR circuit.

19. The semiconductor storage device according to claim 10, wherein the memory cell array includes a plurality of memory cells, each including:
a semiconductor layer extending in a first direction,
a conductive layer facing the semiconductor layer in a second direction intersecting the first direction,
a charge storage layer provided between the semiconductor layer and the conductive layer, and
an insulating layer provided between the semiconductor layer and the charge storage layer.

20. The semiconductor storage device according to claim 10, further comprising:
a plurality of bit lines electrically connected to the memory cell array; and
a sense amplifier circuit electrically connected to one of the bit lines and to the data latch circuit through the first data wiring.
